(19) United States
(12) Patent Application Publication
(10) Pub. No.: US 2024/0283450 A1
(43) Pub. Date: Aug. 22, 2024

(54) Bootstrapped Multiplex Circuit

(71) Applicant: Apple Inc., Cupertino, CA (US)

(72) Inventors: Gary Seigneuret, Munich (DE); Giulio Maria Iadicicco, Munich (DE); Maria Khukhryanskaya, Munich (DE); Emmanuela M. Campolo, Munich (DE)

(21) Appl. No.: 18/172,871

(22) Filed: Feb. 22, 2023

(51) Int. Cl. H03K 17/693; G06F 1/26

(52) U.S. Cl. CPC H03K 17/693; G06F 1/26; H03K 19/018521

(57) ABSTRACT

A multiplex circuit for computer systems includes multiple bootstrap switches that share a common capacitor for generating a boost voltage. When one of the bootstrap switches is activated, it is coupled to the common capacitor which is used to generate the boost voltage to control a switch transistor in the activated bootstrap circuit. Upon deactivating an active bootstrap switch, the common capacitor is pre-charged prior to the activation of another bootstrap switch.

### BACKGROUND

### Technical Field

This disclosure relates to analog circuits in computer systems and, more particularly, to bootstrapped multiplex circuits.

### Description of the Related Art

Modern computer systems may include multiple circuits blocks designed to perform various functions. Such circuit blocks can include both analog and digital circuits. Digital circuits typically perform logical or arithmetic operations using bits of information represented by discrete voltage levels. Analog circuits perform a variety of operations, e.g., amplification, using a continuous range of voltage levels.

Digital circuit blocks may include processor circuits, processor core circuits, microcontroller circuits, and the like. Some processor circuits and processor core circuits may include arithmetic logic units (ALUs) that are used to execute software or program instructions.

Analog circuit blocks may include amplifier circuits, voltage reference circuits, current reference circuits, and the like. In various computer systems, analog circuits may be employed as front-end circuits to amplify and equalize signals received via antennas or wired communication channels. Analog circuits may also be employed to amplify signals for transmission via antennas or wired communication channels.

In some cases, a combination of both analog and digital circuits may be employed within a circuit block. Such circuits, often referred to as mixed-signal circuits, employ a combination of logic gates as well as a variety of analog circuits. Mixed-signal circuits are often employed in converting digital information to analog signals and vice versa.

### BRIEF DESCRIPTION OF THE DRAWINGS

FIG. 1 is a block diagram of an embodiment of a bootstrapped multiplex circuit.

FIG. 2 is a block diagram of an embodiment of a shared capacitor circuit for use with a bootstrapped multiplex circuit.

FIG. 3 is a block diagram of an embodiment of a switch circuit for use with a bootstrapped multiplex circuit.

FIG. 4 is a block diagram of a different embodiment of a shared capacitor circuit for use with a bootstrapped multiplex circuit.

FIG. 5 is a block diagram of a different embodiment of a switch circuit for use with a bootstrapped multiplex circuit.

FIG. 6 is a block diagram of an embodiment of an analog-to-digital conversion subsystem.

FIG. 7 illustrates example waveforms associated with a bootstrapped multiplex circuit.

FIG. 8 is a flow diagram depicting an embodiment of a method for operating a bootstrapped multiplex circuit.

FIG. 9 is a block diagram of one embodiment of a system-on-a-chip that includes a power management circuit.

FIG. 10 is a block diagram of various embodiments of computer systems that may include power management circuits.

FIG. 11 illustrates an example of a non-transitory computer-readable storage medium that stores circuit design information.

While embodiments described in this disclosure may be susceptible to various modifications and alternative forms, specific embodiments thereof are shown by way of example in the drawings and will herein be described in detail. It should be understood, however, that the drawings and detailed description thereto are not intended to limit the embodiments to the particular form disclosed but, on the contrary, the intention is to cover all modifications, equivalents and alternatives falling within the spirit and scope of the appended claims.

### DETAILED DESCRIPTION OF EMBODIMENTS

In computer systems, some resources or circuits can be shared between multiple inputs or signals. Such sharing is accomplished using a multiplex circuit that selects a particular signal from multiple signals based on a state of corresponding control signals. When a given control signal is active, a corresponding input signal is selected as the output of the multiplex circuit.

Multiplex circuits can be used with both analog and digital circuits. In digital circuits, multiplex circuits can be used to implement a programmable logic device in order to realize various logic functions, steer digital signals to a given resource (e.g., a memory circuit), and the like. In analog/mixed-signal circuits, multiplex circuits can be used to select signals from various sources to be processed by an analog circuit. For example, an analog-to-digital converter circuit may employ a multiplex circuit so that it can perform analog-to-digital conversion on data from different sources at different times.

Multiplex circuits used in analog circuits are commonly implemented using multiple transmission gates coupled together in a wired-OR fashion. Such transmission gates are typically implemented using a pair of n-channel and p-channel metal-oxide semiconductor field-effect transistors (MOSFETs). The use of both n-channel and p-channel transistors allows a signal of any voltage level to pass through the transmission gate with little or no attenuation.

Use of p-channel transistors in a transmission gate can, however, result in supply noise injection into the output signal of a multiplex circuit. Any transmission gate that is turned off in the multiplex circuit can allow power supply noise to propagate to the output of the multiplex circuit via the bulk and gate terminals of the p-channel transistors included in the transmission gate. The amount of noise increases as the width, i.e., the number of input signals, of the multiplex circuit increases.

To improve power supply node rejection, a bootstrap switch can be used in place of the conventional transmission gate. In a bootstrap switch, an n-channel transistor is used as the switching element. To ensure that the n-channel transistor is sufficiently activated to minimize its on resistance, a boost voltage is used to activate the n-channel transistor. The boost voltage is typically greater than a power supply voltage used by the bootstrap switch.

To create the boost voltage, a capacitor can be charged to the voltage level of the power supply. When the boost voltage is needed, one terminal of the capacitor is coupled to the gate terminal of the n-channel transistor switching element. The other terminal of the capacitor is coupled to a signal that is greater than ground potential, which couples across the capacitor generating a voltage level greater than the power supply on the gate terminal of the n-channel transistor.

A drawback with the use of bootstrap switches in a multiplex circuit is the increase in circuit area due to the capacitors. The increase in circuit area can translate to additional manufacturing cost as well as result in potential routing issues that can impact performance. In a multiplex circuit implementation, however, only one bootstrap switch is active at any given time. This allows multiple bootstrap switches to share a common capacitor

The embodiments described herein employ multiple bootstrap switches that share a common capacitor in order to implement a bootstrapped multiplex circuit. Since only one input can be selected at a time in a multiplex circuit, only one of the multiple bootstrap switches need be active at any given time, allowing a single capacitor to be shared across time by the multiple bootstrap switches. By sharing a single capacitor, a multiplex circuit can be implemented with the noise benefits associated with using bootstrap switches, but with less circuit area than conventional multiplex circuit implementations.

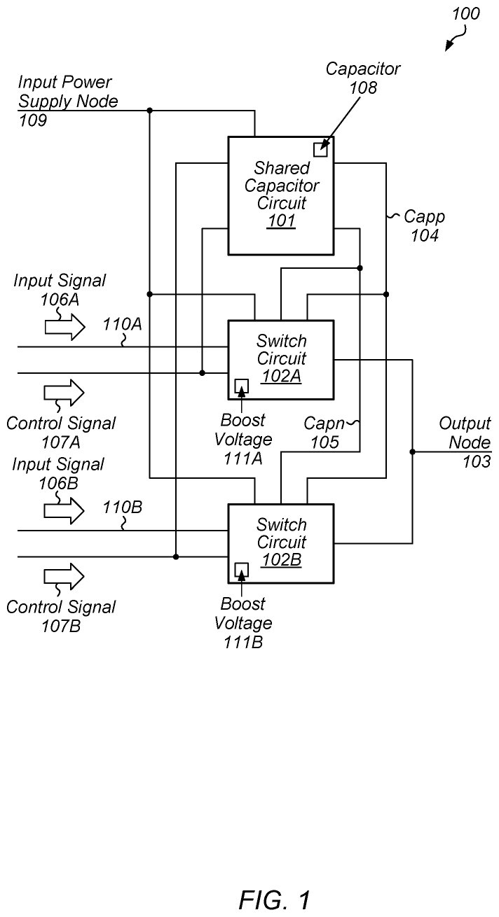

A block diagram depicting an embodiment of a bootstrapped multiplex circuit is illustrated in FIG. 1. As illustrated, bootstrapped multiplex circuit 100 includes switch circuit 102A, switch circuit 102B, and shared capacitor circuit 101, which includes capacitor 108. Although only two switch circuits are depicted in the embodiment of FIG. 1, in other embodiments, any suitable number of switch circuits may be employed.

Switch circuits 102A and 102B are coupled to shared capacitor circuit 101 via nodes capp 104 and capn 105. As described below, nodes capp 104 and capn 105 may be coupled to respective terminals of capacitor 108. Switch circuits 102A and 102B are further coupled to input power supply node 109. As illustrated, switch circuit 102A is coupled between node 110A and output node 103, while switch circuit 102B is coupled between node 110B and output node 103.

Switch circuit 102A is configured to receive input signal 106A via node 110A. In response to an activation of control signal 107A, switch circuit 102A is further configured to generate boost voltage 111A using capacitor 108, whose value is greater than a voltage level of input power supply node 109. Switch circuit 102A is further configured to couple, using boost voltage 111A, input signal 106A to output node 103. It is noted that in some embodiments, control signals, e.g., control signal 107A, may also be referred to as “selection signals.”

In a similar fashion, switch circuit 102B is configured to receive input signal 106B via node 110B and, in response to an activation of control signal 107B, switch circuit 102B is further configured to generate boost voltage 111B using capacitor 108. In various embodiments, boost voltage 111B is greater than the voltage level of input power supply node 109. Switch circuit 102B is further configured to couple, using boost voltage 111B, input signal 106B to output node 103.

As used herein, when a signal is activated, it is set to a logic or voltage level that activates a load circuit or device, and when a signal is deactivated, it is set to a logic or voltage level that deactivates the load circuit or device. The logic level may be either a high logic level or a low logic level depending on the load circuit. For example, an active state of a signal coupled to a p-channel MOSFET is a low logic level (referred to as an “active low signal”), while an active state of a signal coupled to an n-channel MOSFET is a high logic level (referred to as an “active high signal”).

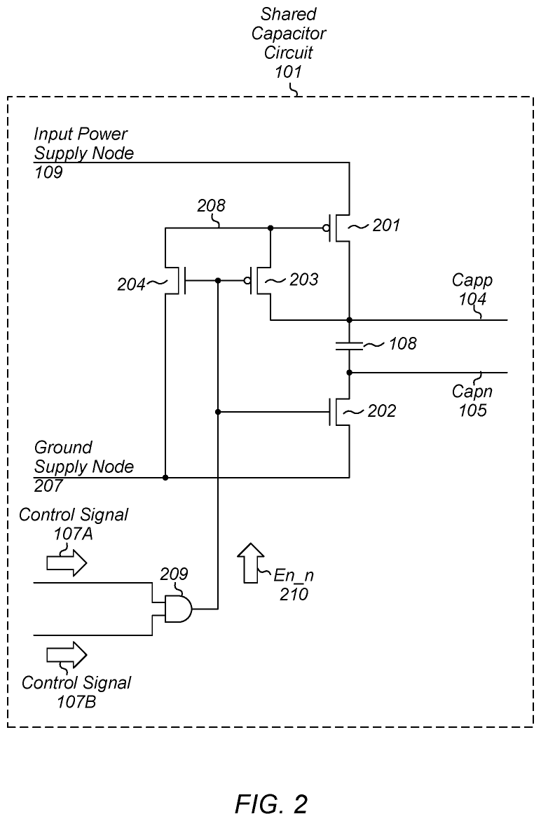

Turning to FIG. 2, a block diagram of an embodiment of shared capacitor circuit 101 is depicted. As illustrated, shared capacitor circuit 101 includes transistors 201-204, capacitor 108, and AND gate 209.

Transistor 201 is coupled between input power supply node 109 and capp 104, and is controlled by a voltage level of node 208. Transistor 204 is coupled between node 208 and ground supply node 207, while transistor 203 is coupled between node 208 and capp 104. Both transistor 203 and transistor 204 are controlled by en_n 210.

Capacitor 108 is coupled between capp 104 and capn 105. Transistor 202 is coupled between capn 105 and ground supply node 107, and is controlled by en_n 210. Although depicted as a single capacitor, in other embodiments, capacitor 108 may be implemented using any suitable parallel combination of capacitors. It is noted that capacitor 108 may be implemented using a metal-oxide-metal (MOM) structure, a metal-insulator-metal (MIM) structure, or any other suitable capacitor structure available on a semiconductor manufacturing process.

In various embodiments, transistors 201 and 203 may be implemented using p-channel metal-oxide semiconductor field-effect transistors (MOSFETs), fin field-effect transistors (FinFETs), gate-all-around field-effect transistors (GAAFETs), or any other suitable transconductance devices. Additionally, transistors 202 and 204 may be implemented using n-channel MOSFETs, FinFETs, GAAFETs, or any other suitable transconductance devices. It is noted that although transistors 201-204 are depicted as being single transistors, in other embodiments, any of transistors 201-204 may be implemented using multiple transistors coupled together in parallel.

AND gate 209 is configured to generate an enable signal (denoted as “en_n 210”) using control signals 107A and 107B. In various embodiments, AND gate 209 is configured to set en_n 210 to a logical-0 value in response to any of control signals 107A and 107B being at a logical-0 value. AND gate 209 is further configured to set en_n 210 to a logical-1 value in response to all of control signals 107A and 107B being logical-1 values.

Although AND gate 209 is depicted as having two inputs, in other embodiments, AND gate 209 may have any suitable number of inputs. In some embodiments, the number of inputs of AND gate 209 may correspond to a number of input signals for boostrapped multiplex circuit 100. In various embodiments, AND gate 209 may be implemented using a NAND gate in combination with an inverter. Alternatively, AND gate 209 may be implemented as a complex gate or any suitable combination of transistors and other logic gates.

When the value of en_n 210 is a logical-1, transistor 204 is activated and transistor 203 is deactivated. Transistor 204, while activated, couples node 208 to ground supply node 207. As node 208 is discharged into ground supply node 207, transistor 201 is activated coupling capp 104 to input power supply node 109. Transistor 202 is also activated when the value of en_n 210 is a logical-1, coupling capn 105 to ground supply node 207. With capp 104 coupled to input power supply node 109 and capn 105 coupled to ground supply node 207, capacitor 108 is charged to the voltage level of input power supply node 109.

In response to a transition of en_n 210 to a logical-0, transistor 204 is deactivated and transistor 203 is activated, which couples node 208 to capp 104. As described above, capp 104 is at the voltage level of input power supply node 109 so when transistor 203 is activated, node 208 is charged to the voltage level of capp 104, deactivating transistor 201. As transistor 201 is deactivated, capp 104 is decoupled from input power supply node 109 and is allowed to float at its current voltage level.

Also in response to the transition of en_n 210 to a logical-0, transistor 202 is deactivated, decoupling capn 105 from ground supply node 207, allowing the voltage level of capn 105 to be controlled by one of switch circuits 102A or 102B as described below.

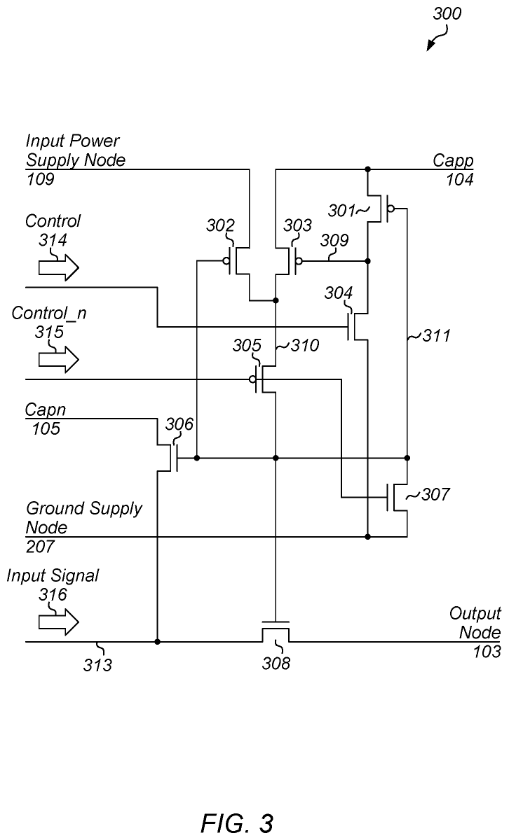

Turning to FIG. 3, a block diagram of an embodiment of a switch circuit is depicted. As illustrated, switch circuit 300 includes transistors 301-308. It is noted that switch circuit 300 may, in various embodiments, correspond to either of switch circuit 102A or 102B.

Transistor 301 is coupled between capp 104 and node 309, and is controlled by a voltage level of node 311. Transistor 302 is coupled between input power supply node 109 and node 310, and is controlled by the voltage level of node 311. In a similar fashion, transistor 303 is coupled between capp 104 and node 310, and is controlled by a voltage level of node 309.

Transistor 304 is coupled between node 309 and ground supply node 207, and is controlled by signal control 314, while transistor 305 is coupled between node 310 and node 311, and is controlled by signal control_n 315. In various embodiments, signals control 314 and control_n 315 are inverses of each other. For example, when signal control 314 is at a logical-1 value, signal control_n 315 is at a logical-0 value. It is noted that signal control 314 may correspond to, or may be derived from, either of control signals 107A or 107B.

Transistor 306 is coupled between capn 105 and node 313, while transistor 307 is coupled between node 311 and ground supply node 207. Transistor 306 is controlled by a voltage level of node 311, while transistor 307 is controlled by signal control_n 315. Transistor 308 is coupled between node 313 and output node 103, and is controlled by the voltage level of node 311. In various embodiments, node 313 may correspond to either of nodes 110A or 110B.

When signal control 314 is set to a logical-0 value and signal control_n 315 is set to a logical-1 value, switch circuit 300 is in an inactive or deactivated state. In this state, transistors 304 and 305 are deactivated, while transistor 307 is activated. In response to the activation of transistor 307, node 311 is coupled to ground supply node 207. As node 311 is discharged to ground, transistor 301 is activated, coupling node 309 to capp 104, charging node 309 which, in turn, deactivates transistor 303. Additionally, as node 311 is discharged, transistor 308 is deactivated, decoupling input signal 316 from output node 103. Moreover, the discharged level on node 311 deactivates transistor 306, decoupling capn 105 from node 313. Additionally, transistor 302 is activated, coupling node 310 to input power supply node 109.

To activate switch circuit 300 so that input signal 316 is coupled to output node 103, signal control 314 and signal control_n 315 are both activated. For example, signal control 314 is set to a logical-1 value, while signal control_n 315 is set to a logical-0 value. In response to an activation of signal control 314, transistor 304 is activated, coupling node 309 to ground supply node 207. As node 309 discharges to ground, transistor 303 is activated, coupling capp 104 to node 310. Since signal control_n 315 is set to a logical-0 value, transistor 305 is activated, coupling node 310 to node 311. As the voltage level of node 311 increases, transistor 306 activates, coupling input signal 316 to capn 105.

As described above in reference to FIG. 2, when input signal 316 is coupled to capn 105, the change in voltage level is coupled to capp 104 via capacitor 108, resulting in a voltage level greater than the voltage level of input power supply node 109 on capp 104, i.e., a boost voltage. The boost voltage is coupled to node 311 via transistors 303 and 305, activating transistor 308, which couples input signal 316 to output node 103. Since the boost voltage is greater than the voltage level of input power supply node 109, the on resistance of transistor 308 is reduced, and the linearity of transistor 308 is improved.

In various embodiments, transistors 301-303, and 305 may be implemented using p-channel MOSFETs, FinFETs, GAAFETs, or any other suitable transconductance devices. Additionally, transistors 304, and 306-308 may implemented be using n-channel MOSFETs, FinFETs, GAAFETs, or any other suitable transconductance devices. It is noted that although transistors 301-308 are depicted as being single transistors, in other embodiments, any of transistors 301-308 may be implemented using multiple transistors coupled together in parallel.

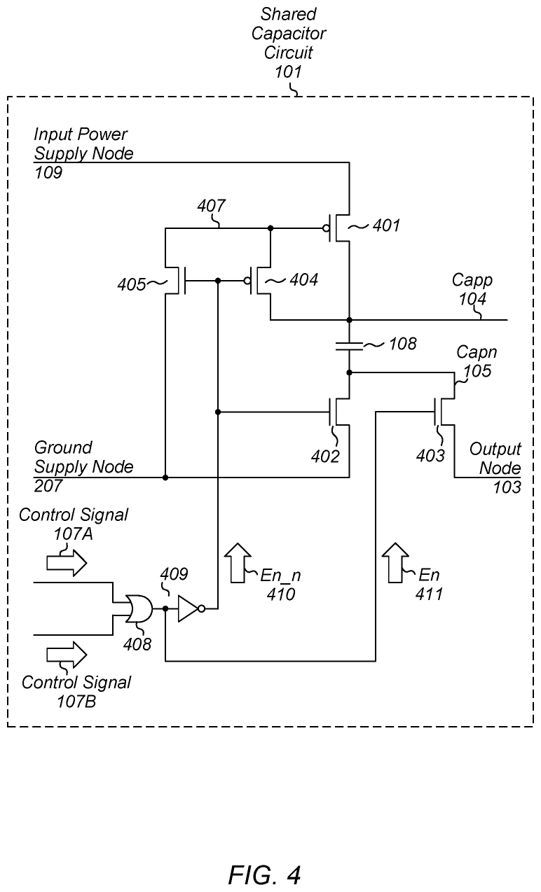

Turning to FIG. 4, a block diagram of a different embodiment of a shared capacitor circuit for use with a bootstrapped multiplex circuit is depicted. In the illustrated embodiment, shared capacitor circuit 101 may be used in conjunction with switch circuits that employ level-shift circuits. As illustrated, shared capacitor circuit 101 includes transistors 401-405, OR gate 408, and inverter 409.

Transistor 401 is coupled between input power supply node 109 and capp 104, and is controlled by a voltage level of node 407. Transistor 405 is coupled between node 407 and ground supply node 207, while transistor 404 is coupled between node 407 and capp 104. Both transistor 404 and transistor 405 are controlled by en_n 410.

Capacitor 108 is coupled between capp 104 and capn 105. Transistor 402 is coupled between capn 105 and ground supply node 207, and is controlled by en_n 410. Transistor 403 is coupled between capn 105 and output node 103 and is also controlled by en_n 410. Although depicted as a single capacitor, in other embodiments, capacitor 108 may be implemented using any suitable parallel combination of capacitors. It is noted that capacitor 108 may be implemented using a metal-oxide-metal (MOM) structure, a metal-insulator-metal (MIM) structure, or any other suitable capacitor structure available on a semiconductor manufacturing process.

In various embodiments, transistors 401 and 404 may be implemented using p-channel MOSFETs, FinFETs, GAAFETs, or any other suitable transconductance devices. Additionally, transistors 402, 403, and 405 may be implemented using n-channel MOSFETs, FinFETs, GAAFETs, or any other suitable transconductance devices. It is noted that although transistors 401-405 are depicted as being single transistors, in other embodiments, any of transistors 401-405 may be implemented using multiple transistors coupled together in parallel.

OR gate 408 is configured to generate signal en 411 using control signals 107A and 107B. Inverter 409 generates signal en_n 410 using en 411. In various embodiments, OR gate 408 is configured to perform a logical-OR operation using control signals 107A and 107B to generate signal en 411, and inverter 409 is configured to generate the logical inverse of signal en 411 to generate signal en_n 410.

Although OR gate 408 is depicted as having two inputs, in other embodiments, OR gate 408 may have any suitable number of inputs. In some embodiments, the number of inputs of OR gate 408 may correspond to a number of input signals for bootstrapped multiplex circuit 100. In various embodiments, OR gate 408 may be implemented using a NOR gate in combination with an inverter. Alternatively, OR gate 408 may be implemented as a complex gate or any suitable combination of transistors and other logic gates. Inverter 409 may, in various embodiments, be implemented using a CMOS inverting amplifier circuit, or any other suitable inverting amplifier circuit including those implemented with technologies other than CMOS.

When the value of signal en_n 410 is a logical-1, signal en 411 is a logical-0. These values of signals en_n 410 and en 411 result in transistors 402, and 405 are activated and transistors 403 and 404 are deactivated. Transistor 405, when activated, couples node 407 to ground supply node 207. As node 407 is discharged into ground supply node 207, transistor 401 is activated, coupling capp 104 to input power supply node 109. Transistor 402, when activated, couples capn 105 to ground supply node 207. With capp 104 coupled to input power supply node 109 and capn 105 coupled to ground supply node 207, capacitor 108 is charged to the voltage level of input power supply node 109. Since transistor 403 is deactivated, capn 105 is isolated from output node 103.

In response to a transition of signal en 411 to a logical-1, signal en_n 410 transitions to a logical-0, which results in the deactivation of transistors 402 and 405, and the activation of transistors 403 and 404. When transistor 405 is deactivated and transistor 404 is activated, node 407 is coupled to capp 104 increasing the voltage on node 407 and deactivating transistor 401, which decouples capp 104 from input power supply node 109.

The deactivation of transistor 402 decouples capn 105 from ground supply node, and the activation of transistor 403 couples capn 105 to output node 103. As the voltage level of output node 103 increases when one of switch circuits 102A or 102B is activated, the increase in the voltage level is coupled into capp 104 via capacitor 108, increasing the voltage level of capp 104 to a boost level. In various embodiments, the boost voltage level is greater than the pre-charge voltage of capacitor 108, which is substantially the same as the voltage level of input power supply node 109.

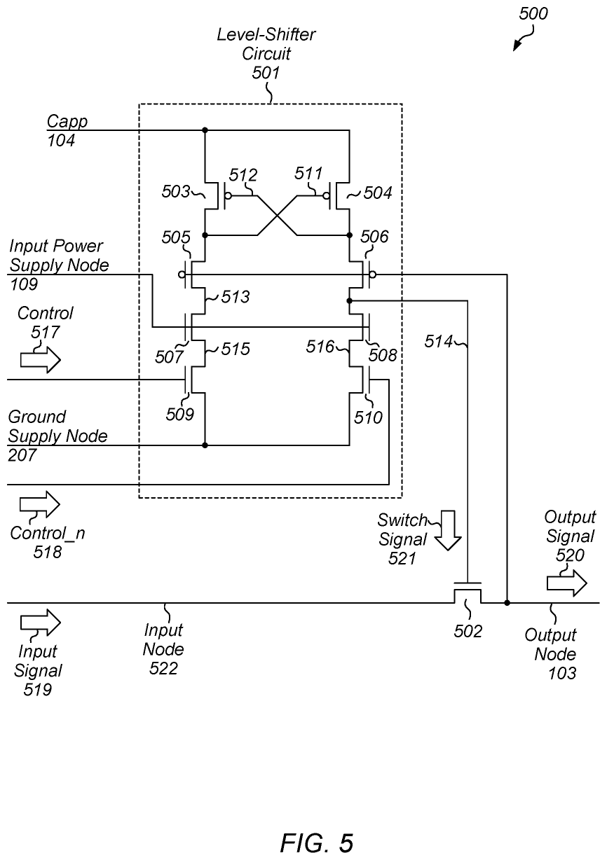

Turning to FIG. 5, a block diagram of a different embodiment of a switch circuit is depicted. As illustrated, switch circuit 500 includes level shifter circuit 501 and transistor 502. Switch circuit 500 includes transistors 503-510. In various embodiments, switch circuit 500 may correspond to either of switch circuits 102A or 102B as depicted in FIG. 1.

Transistor 503 is coupled between capp 104 and node 511, while transistor 504 is coupled between capp 104 and node 512. Transistor 503 is controlled by a voltage level of node 512, and transistor 504 is controlled by a voltage level of node 511. Transistor 505 is coupled between nodes 511 and 513, while transistor 506 is coupled between nodes 512 and 514. Both transistors 505 and 506 are controlled by output signal 520.

Transistor 507 is coupled between nodes 513 and 515, while transistor 508 is coupled between nodes 514 and 516. Both transistors 507 and 508 are controlled by a voltage level of input power supply node 109. Transistor 509 is coupled between node 515 and ground supply node 207, and is controlled by signal control 517. In a similar fashion, transistor 510 is coupled between node 516 and ground supply node 207, and is controlled by signal control_n 518. It is noted that signals control 517 and control_n 518 may correspond to, or may be derived from, control signals 107A and 107B as depicted in FIG. 1.

Transistor 502 is coupled between input node 522 and output node 103. In various embodiments, transistor 502 is configured to couple input node 522 to output node 103 based on switch signal 521, allowing input signal 519 to propagate to output node 103. It is noted that input signal 519 may correspond to either of input signals 106A or 106B as depicted in FIG. 1. As described below, a voltage level of switch signal 521 can be greater than the voltage level of input power supply node 109, which reduces the on resistance of transistor 502 allowing input signal 519 to propagate to output node 103 with minimal attenuation.

Level-shifter circuit 501 translates the level of signal control 517 from its generated level to the voltage level of capp 104 to generate switch signal 522. As described above in regard to FIG. 4, when activated, shared capacitor circuit 101 can generate a voltage level on capp 104 that is greater than the voltage level of input power supply node 109. When signal control 517 is activated, i.e., transitioned to a logical-1 value, signal control_n 518 is transitioned to a logical-0 value. The activation of signal control 517, activates transistor 509, which discharges nodes 515, 513 and 511 into ground supply node 207. As node 511 discharges, transistor 504 is activated, coupling capp 104 to node 506 which is, in turn, coupled to node 514 to generate switch signal 512 at the increased voltage level of capp 104. Although transistor 508 is active, transistor 510 is inactive due to signal control_n 518 being at a logical-0 value, thereby preventing a conduction path from capp 104 to ground supply node 207.

It is noted that transistors 507 and 508 can, in various embodiments, limit the source voltages of transistors 509 and 510 to the voltage level of input power supply node 109 less an n-channel transistor threshold. This can prevent transistors 509 and 510 from operating outside their respective safe operating areas (“SOAs”). In a similar fashion, transistors 505 and 506 limit the source voltages of transistors 503 and 504 to the voltage level of output signal 520 plus a p-channel transistor threshold so that devices 503 and 504 can operate in their respective SOAs.

Transistors 503-506 may, in various embodiments, be implemented using p-channel MOSFETs, FinFETs, GAAFETS, or any other suitable transconductance devices. Additionally, transistors 502 and 507-510 may be implemented using n-channel MOSFETs, FinFETs, GAAFETs, or any other suitable transconductance devices.

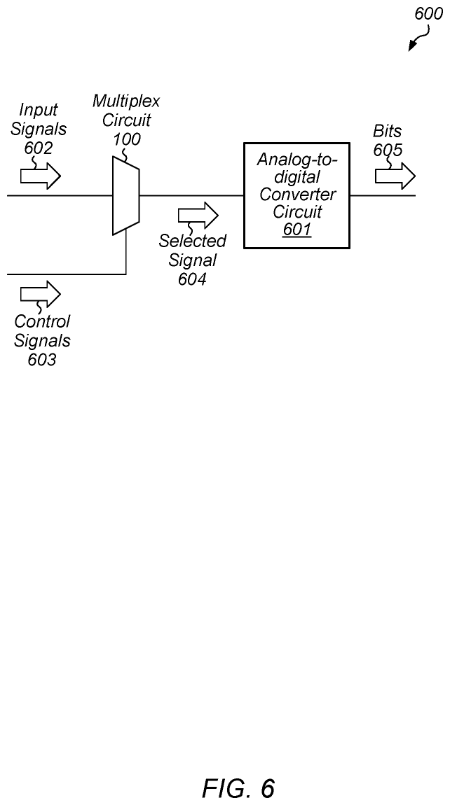

A block diagram of an embodiment of an analog-to-digital conversion subsystem is depicted in FIG. 6. As illustrated, analog-to-digital conversion subsystem includes bootstrapped multiplex circuit 100 and analog-to-digital converter circuit 601.

As described above, bootstrapped multiplex circuit 100 is configured to generate selected signal 604 by selecting a particular one of input signals 602 in response to an activation of a corresponding one of control signals 603. In various embodiments, bootstrapped multiplex circuit 100 may employ n-channel MOSFETs, FinFETs, GAAFETS, and the like, as switch transistors in order to reduce power supply noise injection into selected signal 604.

Analog-to-digital converter circuit 601 is configured to generate bits 605 using selected signal 604. In various embodiments, a collective values of bits 605 may correspond to a magnitude of selected signal 604 at a particular point in time. In some cases, analog-to-digital converter circuit 601 may generate a single value of bits 605 at a particular point in time, or it may generate multiple values for bits 605 over a period of time during which selected signal 604 is active. It is noted that during a pre-charge time for bootstrapped multiplex circuit 100, analog-to-digital converter circuit 601 may be deactivated or otherwise held in an inactive state until a new one of input signals 602 can be selected to generate selected signal 604.

In various embodiments, analog-to-digital converter circuit 601 may be implemented as a flash analog-to-digital converter circuit (or “flash ADC”) in which selected signal 604 is compared to multiple reference voltages using multiple comparator circuits. Alternatively, analog-to-digital converter circuit 601 may be implemented as a successive-approximation analog-to-digital converter circuit, or any other suitable analog-to-digital converter circuit architecture.

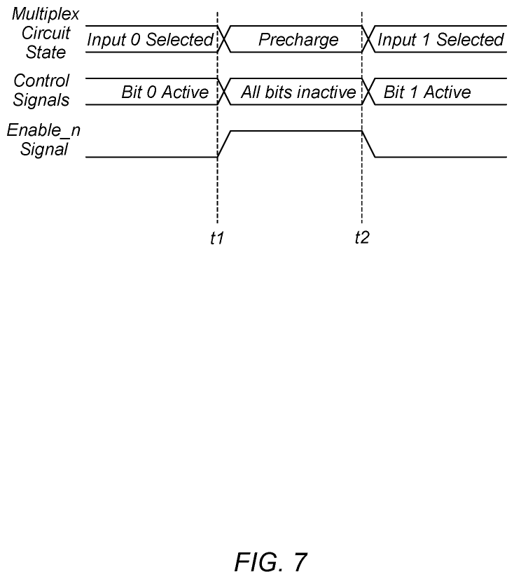

Since the capacitor included in shared capacitor circuit 101 in bootstrapped multiplex circuit 100 is shared by switch circuits 102A-102B, the capacitor must be pre-charged between the activation of different ones of switch circuits 102A-102B. A diagram depicting example waveforms associated with pre-charging the capacitor is illustrated in FIG. 7.

Prior to time t1, the state of bootstrapped multiplex circuit 100 is that input 0 is selected. In various embodiments, this may correspond to an activation of control signal 107A which, in turn, activates switch circuit 102A. It is noted that control signals 107A and 107B may corresponding to respective bits of a multiple bit control signal. For example, an activation of control signal 107A may correspond to bit 0 of the multiple bit control signal being activated.

At time, t1, all of the bits of the control signals, e.g., control signals 107A and 107B, are deactivated. In response to the deactivation of the control signals, enable_n signal is deactivated, i.e., set to a logical-1, to initiate a pre-charge operation. In various embodiments, enable_n signal may correspond to either of en_n 210 or en_n 410. When enable_n is deactivated, the shared capacitor, e.g., capacitor 108 or capacitor 406, is charged to a voltage level of input power supply node 109.

At time t2, bit 1 of the control signals is activated. In various embodiments, bit 1 of the control signals may correspond to control signal 107B. With the activation of bit 1 of the control signal, enable_n signal is activated, i.e., set to a logical-0 value, which allows the shared capacitor to be coupled to one of switch circuits 102A or 102B. The duration of time between time t1 and time t2 may, in various embodiments, depend on a value of the shared capacitor, an amount of current that can be sourced to the capacitor during pre-charge, or any other suitable metric.

The waveforms illustrated in FIG. 7 are merely examples. In other embodiments, different relative timings between the various signals are possible and contemplated.

To summarize, various embodiments of a bootstrapped multiplex circuit are disclosed. Broadly speaking, an apparatus is contemplated in which a shared capacitor circuit, that includes a capacitor, is coupled to first and second switch circuits. The first and second switch circuits are further coupled to an input power supply node, and the first switch circuit is coupled between a first input node and a common output node, and the second switch circuit is coupled between a second input node and the common output node. The first switch circuit is configured to receive a first input signal via the first input node. In response to an activation of a first control signal, the first switch circuit is further configured to generate a first boost voltage using the capacitor, where the first boost voltage is greater than a voltage level of the input power supply node. The first switch circuit is further configured, in response to the activation of the first control signal, to couple, using the first boost voltage, the first input signal to the common output node.

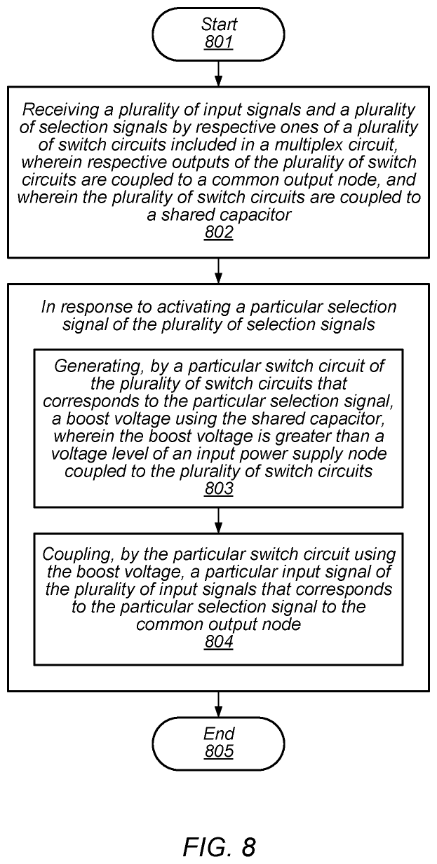

Turning to FIG. 8, a flow diagram depicting an embodiment of a method for operating a bootstrapped multiplex circuit is illustrated. The method, which begins at block 801, may be applied to various bootstrapped multiplex circuits including bootstrapped multiplex circuit 100 as depicted in FIG. 1.

The method includes receiving a plurality of input signals and a plurality of selection signals by respective ones of a plurality of switch circuits included in a multiplex circuit (block 802). In various embodiments, the plurality of switch circuits are coupled to a shared capacitor, and respective outputs of the plurality of switch circuits are coupled to a common output node.

The method further includes, in response to activating a particular selection signal of the plurality of selection signals, generating, by a particular switch circuit of the plurality of switch circuits that corresponds to the particular selection signal, a boost voltage using the shared capacitor (block 803). In some embodiments, the boost voltage is greater than a voltage level of an input power supply node coupled to the plurality of switch circuits. In various embodiments, generating the boost voltage may include coupling a first terminal of the shared capacitor to a level-shifter circuit, and coupling a second terminal of the shared capacitor to the common output node.

The method also includes, in response to activating the particular selection signal, coupling, by the particular switch circuit using the boost voltage, a particular input signal of the plurality of input signals that corresponds to the particular selection signal to the common output node (block 804). In some embodiments, coupling the particular input signal to the common output node includes coupling a first terminal of the shared capacitor to a control terminal of a switch transistor included in the particular switch circuit, where the switch transistor is coupled to the common output node. In such cases, generating the boost voltage may include coupling a second terminal of the shared capacitor to the particular input signal.

In some embodiments, the method further includes, in response to deactivating the particular selection signal, decoupling, by the particular switch circuit, the particular input signal from the common output node, and pre-charging the shared capacitor. The method may also include, in response to determining that the shared capacitor has been pre-charged, activating a different selection signal of the plurality of selection signals.

In various embodiments, the method further includes generating, by an analog-to-digital converter circuit, a plurality of bits using the particular input signal which is coupled to the common output node. The method concludes in block 805.

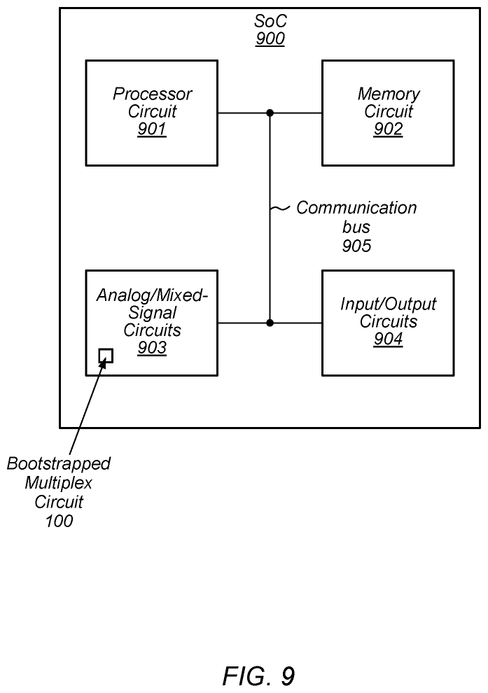

A block diagram of a system-on-a-chip (SoC) is illustrated in FIG. 9. In the illustrated embodiment, SoC 900 includes processor circuit 901, memory circuit 902, analog/mixed-signal circuits 903, and input/output circuits 904, each of which is coupled to communication bus 905. In various embodiments, SoC 900 may be configured for use in a desktop computer, server, or in a mobile computing application such as, e.g., a tablet, laptop computer, or wearable computing device.

Processor circuit 901 may, in various embodiments, be representative of a general-purpose processor that performs computational operations. For example, processor circuit 901 may be a central processing unit (CPU) such as a microprocessor, a microcontroller, an application-specific integrated circuit (ASIC), or a field-programmable gate array (FPGA).

Memory circuit 902 may, in various embodiments, include any suitable type of memory such as a Dynamic Random-Access Memory (DRAM), a Static Random-Access Memory (SRAM), a Read-Only Memory (ROM), an Electrically Erasable Programmable Read-only Memory (EEPROM), or a non-volatile memory, for example. It is noted that although a single memory circuit is illustrated in FIG. 9, in other embodiments, any suitable number of memory circuits may be employed.

As illustrated, analog/mixed-signal circuits 903 includes bootstrapped multiplex circuit 100. In various embodiments, analog/mixed-signal circuits 903 may also include a crystal oscillator circuit, a phase-locked loop (PLL) circuit, an analog-to-digital converter (ADC) circuit, and a digital-to-analog converter (DAC) circuit (all not shown). In other embodiments, analog/mixed-signal circuits 903 may be configured to perform power management tasks with the inclusion of on-chip power supplies and voltage regulator circuits.

Input/output circuits 904 may be configured to coordinate data transfer between SoC 900 and one or more peripheral devices. Such peripheral devices may include, without limitation, storage devices (e.g., magnetic or optical media-based storage devices including hard drives, tape drives, CD drives, DVD drives, etc.), audio processing subsystems, or any other suitable type of peripheral devices. In some embodiments, input/output circuits 904 may be configured to implement a version of Universal Serial Bus (USB) protocol or IEEE 1394 (Firewire®) protocol.

Input/output circuits 904 may also be configured to coordinate data transfer between SoC 900 and one or more devices (e.g., other computing systems or integrated circuits) coupled to SoC 900 via a network. In one embodiment, input/output circuits 904 may be configured to perform the data processing necessary to implement an Ethernet (IEEE 802.3) networking standard such as Gigabit Ethernet or 10-Gigabit Ethernet, for example, although it is contemplated that any suitable networking standard may be implemented. In some embodiments, input/output circuits 904 may be configured to implement multiple discrete network interface ports.

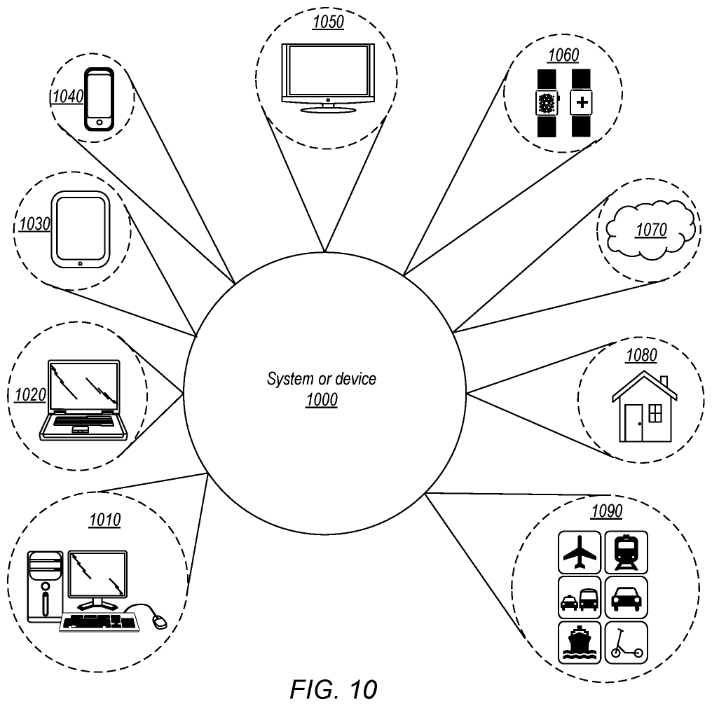

Turning now to FIG. 10, various types of systems that may include any of the circuits, devices, or systems discussed above are illustrated. System or device 1000, which may incorporate or otherwise utilize one or more of the techniques described herein, may be utilized in a wide range of areas. For example, system or device 1000 may be utilized as part of the hardware of systems such as a desktop computer 1010, laptop computer 1020, tablet computer 1030, cellular or mobile phone 1040, or television 1050 (or set-top box coupled to a television).

Similarly, disclosed elements may be utilized in a wearable device 1060, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1000 may also be used in various other contexts. For example, system or device 1000 may be utilized in the context of a server computer system, such as a dedicated server or on shared hardware that implements a cloud-based service 1070. Still further, system or device 1000 may be implemented in a wide range of specialized everyday devices, including devices 1080 commonly found in the home such as refrigerators, thermostats, security cameras, etc. The interconnection of such devices is often referred to as the “Internet of Things” (IoT). Elements may also be implemented in various modes of transportation. For example, system or device 1000 could be employed in the control systems, guidance systems, entertainment systems, etc. of various types of vehicles 1090.

The applications illustrated in FIG. 10 are merely exemplary and are not intended to limit the potential future applications of disclosed systems or devices. Other example applications include, without limitation: portable gaming devices, music players, data storage devices, unmanned aerial vehicles, etc.

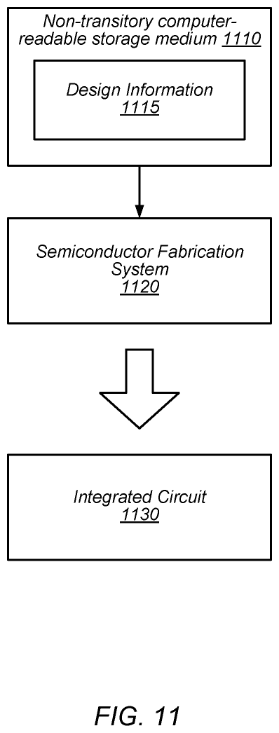

FIG. 11 is a block diagram illustrating an example of a non-transitory computer-readable storage medium that stores circuit design information, according to some embodiments. In the illustrated embodiment, semiconductor fabrication system 1120 is configured to process design information 1115 stored on non-transitory computer-readable storage medium 1110 and fabricate integrated circuit 1130 based on design information 1115.

Non-transitory computer-readable storage medium 1110 may comprise any of various appropriate types of memory devices or storage devices. Non-transitory computer-readable storage medium 1110 may be an installation medium, e.g., a CD-ROM, floppy disks, or tape device; a computer system memory or random-access memory such as DRAM, DDR RAM, SRAM, EDO RAM, Rambus RAM, etc.; a non-volatile memory such as Flash, magnetic media, e.g., a hard drive, or optical storage; registers, or other similar types of memory elements, etc. Non-transitory computer-readable storage medium 1110 may include other types of non-transitory memory as well or combinations thereof. Non-transitory computer-readable storage medium 1110 may include two or more memory mediums, which may reside in different locations, e.g., in different computer systems that are connected over a network.

Design information 1115 may be specified using any of various appropriate computer languages, including hardware description languages such as, without limitation: VHDL, Verilog, SystemC, System Verilog, RHDL, M, MyHDL, etc. Design information 1115 may be usable by semiconductor fabrication system 1120 to fabricate at least a portion of integrated circuit 1130. The format of design information 1115 may be recognized by at least one semiconductor fabrication system, such as semiconductor fabrication system 1120, for example. In some embodiments, design information 1115 may include a netlist that specifies elements of a cell library, as well as their connectivity. One or more cell libraries used during logic synthesis of circuits included in integrated circuit 1130 may also be included in design information 1115. Such cell libraries may include information indicative of device or transistor-level netlists, mask design data, characterization data, and the like, of cells included in the cell library.

Integrated circuit 1130 may, in various embodiments, include one or more custom macrocells, such as memories, analog or mixed-signal circuits, and the like. In such cases, design information 1115 may include information related to included macrocells. Such information may include, without limitation, schematics capture database, mask design data, behavioral models, and device or transistor-level netlists. As used herein, mask design data may be formatted according to graphic data system (GDSII), or any other suitable format.

Semiconductor fabrication system 1120 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1120 may also be configured to perform various testing of fabricated circuits for correct operation.

In various embodiments, integrated circuit 1130 is configured to operate according to a circuit design specified by design information 1115, which may include performing any of the functionality described herein. For example, integrated circuit 1130 may include any of various elements shown or described herein. Further, integrated circuit 1130 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components.

The present disclosure includes references to “embodiments,” which are non-limiting implementations of the disclosed concepts. References to “an embodiment,” “one embodiment,” “a particular embodiment,” “some embodiments,” “various embodiments,” and the like do not necessarily refer to the same embodiment. A large number of possible embodiments are contemplated, including specific embodiments described in detail, as well as modifications or alternatives that fall within the spirit or scope of the disclosure. Not all embodiments will necessarily manifest any or all of the potential advantages described herein.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

Particular features, structures, or characteristics may be combined in any suitable manner consistent with this disclosure. The disclosure is thus intended to include any feature or combination of features disclosed herein (either explicitly or implicitly), or any generalization thereof. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

For example, while the appended dependent claims are drafted such that each depends on a single other claim, additional dependencies are also contemplated. Where appropriate, it is also contemplated that claims drafted in one statutory type (e.g., apparatus) suggest corresponding claims of another statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to the singular forms such “a,” “an,” and “the” are intended to mean “one or more” unless the context dictates otherwise. Reference to “an item” in a claim thus does not preclude additional instances of the item.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” covering x but not y, y but not x, and both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of options. This phrase is not to be interpreted to require that there is at least one instance of w, at least one instance of x, at least one instance of y, and at least one instance of z.

Various “labels” may proceed nouns in this disclosure. Unless context provides otherwise, different labels used for a feature (e.g., “first circuit,” “second circuit,” “particular circuit,” “given circuit,” etc.) refer to different instances of the feature. The labels “first,” “second,” and “third,” when applied to a particular feature, do not imply any type of ordering (e.g., spatial, temporal, logical, etc.), unless stated otherwise.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function. This unprogrammed FPGA may be “configurable to” perform that function, however.

Reciting in the appended claims that a structure is “configured to” perform one or more tasks is expressly intended not to invoke 35 U.S.C. § 112(f) for that claim element. Should Applicant wish to invoke Section 112(f) during prosecution, it will recite claim elements using the “means for” [performing a function] construct.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

What is claimed is:

1. An apparatus, comprising:
a shared capacitor circuit including a capacitor;
a first switch circuit coupled to the shared capacitor circuit and an input power supply node, and coupled between a first input node and a common output node; and
a second switch circuit coupled to the shared capacitor circuit and the input power supply node, and coupled between a second input node and the common output node; and
wherein the first switch circuit is configured to:
receive a first input signal via the first input node; and
in response to an activation of a first control signal, to:
generate a first boost voltage using the capacitor, wherein the first boost voltage is greater than a voltage level of the input power supply node; and
couple, using the first boost voltage, the first input signal to the common output node.

2. The apparatus of claim 1, wherein the shared capacitor circuit is configured to perform a pre-charge operation on the capacitor in response to a determination that a first selection signal has been deactivated.

3. The apparatus of claim 2, wherein the shared capacitor circuit is further configured to halt the pre-charge operation in response to an activation of a second selection signal, and wherein the second switch circuit is further configured, in response to the activation of the second selection signal, to:
generate a second boost voltage using the capacitor, wherein the second boost voltage is greater than the voltage level of the input power supply node; and
couple, using the second boost voltage, a second input signal to the common output node.

4. The apparatus of claim 1, wherein the first switch circuit includes a switch transistor coupled between an input node and the common output node, and wherein to couple the first input signal to the common output node, the first switch circuit is configured to couple a control terminal of the switch transistor to a first terminal of the capacitor.

5. The apparatus of claim 4, wherein to generate the first boost voltage, the first switch circuit is further configured to couple the first input node to a second terminal of the capacitor.

6. The apparatus of claim 1, wherein the first switch circuit includes a level-shifter circuit coupled to a first terminal of the capacitor, and wherein the level-shifter circuit is configured to generate the boost voltage based on a voltage level of the common output node.

7. A method, comprising:
receiving a plurality of input signals and a plurality of selection signals by respective ones of a plurality of switch circuits included in a multiplex circuit, wherein respective outputs of the plurality of switch circuits are coupled to a common output node, and wherein the plurality of switch circuits are coupled to a shared capacitor; and
in response to activating a particular selection signal of the plurality of selection signals:
generating, by a particular switch circuit of the plurality of switch circuits that corresponds to the particular selection signal, a boost voltage using the shared capacitor, wherein the boost voltage is greater than a voltage level of an input power supply node coupled to the plurality of switch circuits; and
coupling, by the particular switch circuit using the boost voltage, a particular input signal of the plurality of input signals that corresponds to the particular selection signal to the common output node.

8. The method of claim 7, further comprising, in response to deactivating the particular selection signal:
decoupling, by the particular switch circuit, the particular input signal from the common output node; and
pre-charging the shared capacitor.

9. The method of claim 8, further comprising, in response to determining that the shared capacitor has been pre-charged, activating a different selection signal of the plurality of selection signals.

10. The method of claim 7, wherein coupling the particular input signal to the common output node includes coupling a first terminal of the shared capacitor to a control terminal of a switch transistor included in the particular switch circuit, wherein the switch transistor is coupled to the common output node.

11. The method of claim 10, wherein generating the boost voltage includes coupling a second terminal of the shared capacitor to the particular input signal.

12. The method of claim 7, wherein generating the boost voltage includes:
coupling a first terminal of the shared capacitor to a level-shifter circuit; and
coupling a second terminal of the shared capacitor to the common output node.

13. The method of claim 7, further comprising, generating, by an analog-to-digital converter circuit, a plurality of bits using the particular input signal when it is coupled to the common output node.

14. An apparatus, comprising:
a multiplex circuit including a plurality of switch circuits coupled to a shared capacitor and a common output node, wherein the multiplex circuit is configured to:
receive a plurality of input signals;
receive a plurality of control signals; and
in response to an activation of a particular control signal of the plurality of control signals:
generate a boost voltage by a particular switch circuit of the plurality of switch circuits that corresponds to the particular control signal using the shared capacitor; and
couple, by the particular switch circuit using the boost voltage, a particular input signal of the plurality of input signals that corresponds to the particular control signal to the common output node to generate an output signal on the common output node; and
an analog-to-digital converter circuit configured to generate a plurality of bits based on the output signal.

15. The apparatus of claim 14, wherein the multiplex circuit is further configured, in response to a deactivation of the particular control signal, to:
decouple the particular input signal from the common output node; and
pre-charge the shared capacitor.

16. The apparatus of claim 15, wherein the multiplex circuit is further configured, in response to a determination that the shared capacitor has been pre-charged, to respond to an activation of a different control signal of the plurality of control signals.

17. The apparatus of claim 15, wherein to pre-charge the shared capacitor, the multiplex circuit is further configured to couple the shared capacitor between an input power supply node and a ground supply node.

18. The apparatus of claim 14, wherein to couple the particular input signal to the common output node, the multiplex circuit is further configured to couple a first terminal of the shared capacitor to a control terminal of a switch transistor included in the particular switch circuit, wherein the switch transistor is coupled to the common output node.

19. The apparatus of claim 18, wherein to generate the boost voltage, the multiplex circuit is further configured to couple a second terminal of the shared capacitor to the particular input signal.

20. The apparatus of claim 14, wherein to generate the boost voltage, the multiplex circuit is further configured to:
couple a first terminal of the shared capacitor to a level-shifter circuit included in the multiplex circuit; and
couple a second terminal of the shared capacitor to the common output node.
